(19) United States
(12) Patent Application Publication
(10) Pub. No.: US 2020/0362456 A1
(43) Pub. Date: Nov. 19, 2020

(54) SOLID MATERIAL CONTAINER AND SOLID MATERIAL PRODUCT IN WHICH SAID SOLID MATERIAL CONTAINER IS FILLED WITH A SOLID MATERIAL

(71) Applicant: L'Air Liquide, Société Anonyme pour I'Etude et I'Exploitation des Procédés Georges Claude, Paris (FR)

(72) Inventors: Toshiyuki NAKAGAWA, Hyogo (JP); Mikio GOTO, Tokyo (JP); Kazuma SUZUKI, Tsukuba (JP); Toru AOYAMA, Tsukuba (JP); Takashi KAMEOKA, Tsukuba (JP); Kazutaka YANAGITA, Tsukuba (JP)

(21) Appl. No.: 16/766,014

(22) PCT Filed: Nov. 16, 2018
(86) PCT No.: PCT/EP2018/081626

§ 371 Date: May 21, 2020

(30) Foreign Application Priority Data
Nov. 22, 2017 (JP) 2017-225035

(51) Int. Cl. C23C 16/448; C23C 16/442

(52) U.S. Cl. CPC C23C 16/4481; C23C 16/442

(57) ABSTRACT

A solid material container 1 for gasifying and supplying a solid material 25 stored therein has a metal outer unit 21 and a metal inner unit 22. The inner unit 22 is contained inside the outer unit 21, projections 31 are formed inside the outer unit 21, and a bottom section of the inner unit 22 has an inner section fitting section, which removably fits onto the projections 31 with the outer unit 21.

### CROSS REFERENCE TO RELATED APPLICATIONS

This application is a 371 of International PCT Application PCT/EP2018/081626, filed Nov. 16, 2018, which claims priority to Japanese Patent Application No. 2017-225035, filed Nov. 22, 2017, the entire contents of which are incorporated herein by reference.

### BACKGROUND

The present invention relates to a solid material container for supplying vapor of a semiconductor manufacturing material, e.g., a solid material for manufacturing a thin film, and a solid material product in which the solid material container is filled with the solid material.

As the semiconductor industry has advanced, there has been a demand for use of new precursor materials which might satisfy strict film requirements. These materials are used for a wide range of purposes in thin-film deposition and machining of semiconductor products.

Examples of solid precursor materials include the constituent components for barrier layers, high-dielectric-constant/low-dielectric-constant insulation layers, metal electrode layers, connection layers, ferroelectric layers, and silicon nitride layers or silicon oxide layers. Additional examples of solid precursors include constituent components acting as dopants for compound semiconductors, and etching materials. Exemplary precursor materials include inorganic compounds and organic metal compounds of aluminum, barium, bismuth, chrome, cobalt, copper, gold, hafnium, indium, iridium, iron, lanthanum, lead, magnesium, molybdenum, nickel, niobium, platinum, ruthenium, silver, strontium, tantalum, titanium, tungsten, yttrium, and zirconium.

Since some of these new materials are in solid form at standard temperatures and pressures, they cannot be directly supplied into semiconductor film formation chambers in the manufacturing process.

In general, these materials have extremely high melting points and low vapor pressures, and must therefore be gasified or sublimated within a narrow range of temperatures and pressures before being supplied to the film formation chamber. Moreover, to obtain a uniform thin-film, the solid material must be introduced uniformly during a constant thin-film formation process.

Several techniques for gasifying and sublimating solid materials have been developed. For example, Patent Literature 1 and Patent Literature 2 propose methods for disposing a plurality of trays filled with solid materials horizontally inside a solid material container.

### PRIOR ART LITERATURE

Patent Literature 1: JP 2008-501507 A, Japanese translation of PCT application.

Patent Literature 2: JP 2011-509351 A, Japanese translation of PCT application.

The solid material containers disclosed in Patent Literature 1 and Patent Literature 2 are configured such that disk-shaped trays are inserted into a cylindrical outer unit. The outer unit and the trays are not secured to each other.

Therefore, if the outer dimension of the trays is smaller than then inner dimension of the outer unit, the phenomenon of the trays shifting or moving inside the outer unit during transportation or use occurs. Movement of the trays entails the risk of the solid material filling the trays spilling out of the trays.

The solid material filling the trays has a predetermined particle diameter, and any solid material spilling out of the trays tends to get worn between the trays and the outer unit, causing the particle diameter to fall. This creates the problem of inconsistent supply of solid material vapor, because the vapor characteristics of the solid material vary depending on the particle diameter.

Any solid material caught between the trays and the outer unit will be affected by heat entering from outside the solid material container more than the solid material filling the trays. Accordingly, if the solid material container is heated to a temperature appropriate for vaporizing the solid material filling the trays, the solid material caught between the tray and the outer unit will be heated to excess. The solid material which is heated to excess undergoes thermal breakdown, creating impurities, solidifying and blocking flow paths for the vapor inside the solid material container, and clogging the space between the trays and the outer unit, thereby preventing removal of the trays.

Furthermore, shifting of the trays creates gaps in the surrounding edges of the neighboring trays above and below, as well as gaps between the trays and the outer units, through which carrier gas flows in. When such carrier gas flow paths are formed, solid material vapor supply performance drops markedly.

In general, with solid material having a plurality of trays, the carrier gas travels from the bottom tray to the top tray, but not between the trays and the outer unit, the concentration of the accompanying solid material vapor thereby being kept constant.

However, if carrier gas flows from gaps between the trays to gaps between the trays and the outer unit, the carrier gas is discharged from the solid material without having adequately come in contact with the solid material. Therefore, the concentration of the solid material vapor discharged from the solid material container accompanying the carrier gas falls or becomes unstable.

To prevent solid material or carrier gas from getting between the outer unit and the trays, an outer dimension of the trays can be used which allows insertion of the trays without gaps relative to the inner dimension of the outer unit. This, however, makes insertion and removal of the trays into and out of the outer unit difficult. When inserting or removing trays, there is a significant risk of the trays bumping against the outer unit and scratching the surface of contact. Scratches in the surface of contact cause particles to be created or corrosion because the metal surface becomes rough.

Moreover, the solid material container is often heated during use, and if the trays become attached to the outer unit due to thermal expansion during heating, they become impossible to remove. If they trays cannot be removed, the solid material container cannot be washed and the solid material cannot be refilled.

High precision machining technology is required to make trays which can be inserted into the outer unit without gaps. High-precision machining is particularly difficult when the container is large.

Solid material containers can be made so as to provide gaps between the outer units and the trays. However, in this case, lateral misalignment of the neighboring trays above and below occurs more readily. If misalignment occurs between the stacked trays above and below, the problem occurs of the carrier gas flowing into the gaps created by the misalignment, and there is inadequate contact between the carrier gas and the solid material, as noted above.

On this background, there is a desire for a solid material container having trays inside, wherein spilling of the solid material filling the trays out of the trays can be minimized to be developed, using a simple method and configuration.

### SUMMARY

### Invention 1

A solid material container according to the present invention is a solid material container for gasifying and supplying a solid material contained therein, comprising a solid material discharge pipe which discharges vapor of the solid material out of the solid material container, a metal outer unit, and a metal inner unit, wherein the inner unit is contained inside the outer unit and protrusions are formed on the inside of the outer unit, and a bottom section of the inner unit has an inner section fitting section which removably fits onto the protrusions with the outer unit.

The solid material container may further have a carrier gas introduction pipe which introduces a carrier gas into the solid material container.

When the inner unit, which has a smaller outer dimension than the inner dimension of the outer unit, is placed in the metal outer unit, the position of the inner unit could conceivably move inside the outer unit. Accordingly, the solid material container of the present invention has projections formed in the outer unit, and the inner unit has an inner unit fitting section for removably fitting the bottom of the inner unit onto said projections. By fitting the inner unit bottom section into the outer unit, the position of the inner unit inside the outer unit is fixed. Accordingly, scattering of the solid material filling the inner unit out of the inner unit due to movement of the inner unit inside the outer unit can be prevented. Hence, it is possible to minimize the phenomenon whereby the scattered solid material enters between the outer unit and the inner unit, is worn between the inner unit and the outer unit, and the particle diameter falls. This minimizes fluctuations in the characteristics of the solid material vapor caused by changes in the particle diameter, and makes it possible to supply uniform solid material vapor. This can minimize the phenomenon whereby if the solid material caught between the inner unit and the outer unit is heated excessively and suffers thermal breakdown, impurities are created, the solid material solidifies and blocks the vapor flow path inside the solid material container, or the solid material clogs the spaces between the inner unit and the outer unit, preventing removal of the trays.

With the solid material container according to the present invention, an inner unit having an outer unit with a predetermined clearance relative to the inner dimension of the outer unit can be used, since the outer unit and the inner unit are fitted together on the protrusions. There is reduced risk of the solid material scattering into gaps if the fitting between the outer unit and the inner unit is fixed, even if there are such gaps between the outer unit and the inner unit due to the clearance.

By providing this clearance, insertion and removal of the trays into and out of the outer unit is improved. The risk of the trays bumping against the outer unit and scratching the surface of contact when inserting or removing trays can also be reduced. Hence, the creation of particles or corrosion due to scratching of the surface of contact can be reduced.

The phenomenon can also be reduced whereby the inner unit becomes attached to the outer unit and impossible to remove due to the outer unit and the inner unit undergoing thermal expansion when the solid material container is heated.

By making the inner unit fitting section removable from the outer unit and the protrusions, the outer unit and the inner unit can be separated, washed, and dried, etc.

With the solid material container according to the present invention, a clearance is provided between the inner unit and the outer unit, making machining easier.

The size of the clearance is preferable a size which takes into consideration the thermal expansion rate at the temperatures at which the metal and nonmetal materials which are used are used. For example, it is preferable to use a clearance which is greater than the maximum dimension of expansion for a particular coefficient of thermal expansion.

### Invention 2

The solid material container as claimed in the present invention further comprises a lid unit disposed on top of the inner unit, and the lid unit has at least one upper ventilation sections through which vapor of the solid material flows.

With the present invention, the lid unit on top of the inner unit makes it possible to reduce the phenomenon of the solid material scattering out of the inner unit through the top of the inner unit.

With the present invention the solid material which is gasified and becomes vapor is discharged out of the solid material container through the upper ventilation sections with the carrier gas.

The top ventilation sections may be any shape as long as gas can pass through them; they may be circular holes or slit-shaped, and a plurality of holes and slits may be disposed. By disposing the top ventilation sections uniformly in the lid unit, the flow of the solid material vapor inside the inner unit can be made uniform. By making the flow of the solid material vapor uniform, collection of the solid material inside the inner unit can be prevented, and the concentration of the solid material vapor which is discharged can be kept uniform. For example, if the top ventilation units are in a shower shape in which a plurality of circular holes are disposed, the solid material vapor is uniformly discharged from the plurality of holes in a shower arrangement.

### Invention 3

The lid unit of the solid material container according to the present invention has a lid fitting section which removably fits onto the top of the inner unit. With the present invention, the top of the inner unit and the lid unit fit together and are fixed together in the lid unit fitting section, and therefore the inner unit and the lid unit can be prevented from becoming misaligned. Accordingly, the phenomenon can be minimized whereby solid material scatters out from the gaps created by the lid unit and the inner unit shifting, and the solid material enters between the outer unit and the inner unit.

Furthermore, because the lid unit is affixed to the inner unit, the phenomenon of the lid unit bumping against the inner unit or the outer unit and getting scratched can be minimized.

### Invention 4

The inner unit of the solid material container according to the present invention has inner unit side walls and an inner unit bottom section, and the inner unit side walls have a bottom section fitting section which removably fits onto the inner unit bottom section.

In the inner unit, the side wall and the bottom unit may be a single unit, but it is also possible to make the inner unit side walls and the inner unit bottom section separate members and configure the inner unit by removably fitting these together. If the inner unit side walls and the inner unit bottom section are manufactured as separate members, manufacturing and machining are easier than if manufacturing the inner unit as a single member. Furthermore, the phenomenon can be minimized whereby the solid material scatters out of the gaps created by the inner unit side walls and the inner unit bottom section shifting and enters into the gap between the outer unit and the inner unit.

Furthermore, because the inner unit side walls are affixed to the inner unit bottom section, if the inner unit bottom section is affixed to the outer unit in the inner unit fitting section, the phenomenon of the inner unit side walls bumping against the outer unit and getting scratched can be minimized.

### Invention 5

The solid material container according to the present invention, wherein an inner section bottom plate is disposed in the inner unit bottom section, and the inner unit bottom plate has one or more bottom ventilation sections through which the carrier gas passes.

The inner unit bottom plate is disposed so as to disperse the carrier gas and cause the carrier gas to come into contact with the solid material uniformly. The carrier gas introduction pipe is inserted into the inner unit, and extends all the way to under the inner unit bottom plate disposed in the inner unit bottom section. In other words, a carrier gas outlet of the carrier gas introduction pipe opens under the inner unit bottom plate. The carrier gas is fed from the carrier gas outlet in the carrier gas introduction pipe to the bottom of the inner unit bottom plate, passes through the bottom ventilation sections in the inner unit bottom plate, moves to the top of the inner unit bottom plate, and comes in contact with the solid material which fills the inside of the inner unit, which is above the inner unit bottom plate.

The bottom ventilation sections may be any shape as long as gas can pass through them; they may be circular holes or slit-shaped, and a plurality of holes and slits may be disposed. By disposing the bottom ventilation sections uniformly in the inner unit bottom plate, the flow of the carrier gas inside the inner unit can be made uniform. By making the flow of the carrier gas uniform, the carrier gas comes in contact with the solid material uniformly, which can prevent the solid material from collecting inside the inner unit and keep the concentration of the solid material vapor discharged from the inner unit uniform. For example, if the bottom ventilation units are in a shower shape in which a plurality of circular holes are disposed, the solid material vapor is uniformly discharged from the plurality of holes in a shower arrangement.

### Invention 6

The inner unit side walls of the solid material container according to the present invention have plate section top surface fitting sections which removably fit onto a bottom plate top surface section disposed on the top surface of the inner unit bottom plate, and the inner unit bottom section has a plate section bottom surface fitting section which removably fits with a bottom plate bottom surface fitting section disposed on a bottom surface of the inner unit bottom plate.

The inner unit bottom plate can be disposed on the bottom section of the inner unit, in which the inner unit side walls and the inner unit bottom section are a single unit, or the inner unit side walls, the inner unit bottom section, and the inner unit bottom plate can be made individual members and removably fitted together to configure the inner unit. The inner unit bottom plate is disposed on and fitted onto the inner unit, and the inner unit side walls are disposed on and fitted onto the inner unit bottom plate, and thus can the inner unit be configured.

If the inner unit side walls, the inner unit bottom section, and the inner unit bottom plate are manufactured as separate members, manufacturing and machining are easier than if manufacturing everything as a single member. Because the bottom ventilation sections are open in the inner unit bottom plate, it is conceivable that the solid material might fall through the bottom ventilation sections onto the inner unit bottom section, but if it does fall, the solid material merely comes in contact with the inner unit bottom section, and does not scatter into the gap with the outer unit.

Because the inner unit side walls and the inner unit bottom plate, or the inner unit bottom plate and the inner unit bottom section are fitted together, it is possible to minimize the phenomenon of the solid material leaking out through gaps caused by misalignment thereof and coming in contact with the metal outer unit, the solid material thereby scattering into the gap with the outer unit.

Furthermore, because the inner unit side walls are affixed to the inner unit bottom section and the inner unit bottom plate is affixed to the inner unit bottom section, if the inner unit bottom section is affixed to the outer unit in the inner unit fitting section, the phenomenon of the inner unit side walls bumping against the outer unit and breaking can be minimized.

### Invention 7

The inner unit of the solid material container according to the present invention is configured by a plurality of trays which are disposed at fixed intervals vertically, and which are filled with the solid material.

By disposing the plurality of trays filled with the solid material vertically, the carrier gas comes in contact with the surface of the solid material filling the plurality of trays, making it possible to increase the area of contact between the carrier gas and the solid material. Increasing the area of contact with the carrier gas can prevent a drop in vapor concentration of the solid material in the carrier gas caused by insufficient area of contact. The drop in the temperature of the solid material surface due to escape of gasification heat is particularly notable when gasifying the solid material for long periods of time or if the solid material gasification quantity is large. If the temperature of the surface of the solid material falls, the vapor pressure of the solid material where the temperature has fallen also falls, which makes it harder for the solid material to gasify, which in turn causes the concentration of the solid material vapor in the carrier gas discharged from the solid material container to fall and become unstable. In such cases, too, if the area of contact with the carrier gas is increased by disposing a plurality of trays, the solid material vapor can be discharged with a stable concentration, without the temperature of the surface of the solid material falling.

### Invention 8

The plurality of trays in the solid material container according to the present invention comprise at least one first tray which has an outer supporting section on side edges thereof and is smaller than the inner dimension of the outer unit, and at least one second tray, which has an inner supporting section in a central section thereof and is smaller than the outer dimension of the first tray for forming an outer flow path.

The first trays are disposed so as to form a vertical overlapping stack with the second trays.

A flow path is formed between the first trays and the second trays through the outer flow path.

With the present invention, the plurality of trays are disposed such that the first tray and the second tray are overlapping and stacked. If there is a plurality of first trays, they are disposed such that the second tray is sandwiched between one of the first trays and another one of the first trays stacked on top of said first tray. Between the first tray and the second tray, which is smaller than the outer dimension of the first tray is the outer flow path through which passes the solid material vapor accompanied by the carrier gas. The carrier gas which passes over the first tray while coming in contact with the surface of the solid material filling the first tray flows into the second tray through the outer flow path and comes in contact with the surface of the solid material filling the second tray. This arrangement makes it possible for the carrier gas which is introduced into the inner unit to pass through the plurality of trays making up the inner section in order and come in contact with the solid material filling each of the trays. As a result, the area of contact between the surface of the solid material and the carrier gas increases, making it possible to discharge the solid material vapor with a stable concentration.

It is possible for one of the first trays and one of the second trays to be provided, but it is also possible for a plurality of the first trays and a plurality of the second trays to be provided. The number of the first trays and the number of the second trays may be the same, or there may be one more or one less of the first trays than the second trays.

### Invention 9

The first tray of the solid material container according to the present invention has an outer supporting section top fitting section provided to the top of the outer supporting section, and an outer supporting section bottom fitting section provided to the bottom of the outer supporting section.

The second tray has an inner supporting section top fitting section provided to the top of the inner supporting section, and an inner supporting section bottom fitting section provided to the bottom of the inner supporting section.

The outer supporting section top fitting section of at least one of the first trays is removably fitted so as to be stacked on the outer supporting section bottom fitting section of at least one of the vertically neighboring first trays.

The inner supporting section top fitting section of at least one of the first trays is removably fitted so as to be stacked on the inner supporting section bottom fitting section of at least one of the vertically neighboring first trays.

With the present invention, if one of the first trays is disposed so as to be stacked on another of the first trays, the outer supporting section top fitting section of the lower first tray is removably fitted onto the outer supporting section bottom fitting section of the top first tray, the top first tray and the bottom first tray thus being fixed together.

Similarly, if one of the second trays is disposed so as to be stacked on another of the second trays, the inner supporting section top fitting section of the lower second tray is removably fitted onto the inner supporting section bottom fitting section of the top second tray, the top second tray and the bottom second tray thus being fixed together.

Thus, by fitting the outer supporting section of one of the first trays onto the outer supporting section of another of the first trays so as to form a stack, the outer supporting sections are disposed without any gaps vertically. Accordingly, the carrier gas flowing onto the first tray flows through the outer flow path onto the second tray, without leaking out of the outer supporting sections towards the outer container. By fitting the outer supporting sections together, no carrier gas flows into any gaps between the outer supporting sections and the outer unit. Therefore, it is possible to minimize the carrier gas flowing between the outer unit and the outer supporting sections without coming in contact with the solid material and being discharged towards the back of the solid material container without being accompanied by the solid material vapor (or without sufficient solid material vapor accompanying it).

Similarly, by fitting the inner supporting section of one of the second trays onto the inner supporting section of another of the second trays so as to form a stack, the inner supporting sections are disposed without any gaps vertically. A pillar-shaped space can be provided to the center of the inner supporting sections, By disposing the inner supporting sections in this manner and disposing the carrier gas introduction pipe in the pillar-shaped space, the stacked inner supporting sections can form the pipe cover unit.

### Invention 10

The present invention is also a solid material product in which a solid material fills the solid material container.

The solid material may be a precursor used in depositing a semiconductor layer. The solid material may be the precursor itself, or the solid material carried on a carrier body such as beads, etc. The solid material may be in a solid state when being filled, it may be a solid material when the solid material container is being transported, and it may be in a liquid state when being filled or when being heated after being filled. There is no particular limitation on the solid material, which may be a material including a compound selected from the group consisting of an organic compound, an organic metal compound, a metal halogen compound, and mixtures of these. It may be AlCl₃, HfCl₄, WCl₆, WCl₅, NbF₅, TiF₄, XeF₂, or carboxylic acid anhydride, for example. The solid material may directly fill the solid material when connected to the semiconductor device, The solid material may fill the solid material container after the solid material container has been removed from the semiconductor device.

With the present invention, a solid material container can be provided which has an inner unit and trays inside and the inner unit or trays are filled with a solid material, wherein the solid material filling the inner unit or the trays can be prevented from scattering out of the inner unit or trays.

### BRIEF DESCRIPTION OF THE DRAWINGS

For a further understanding of the nature and objects for the present invention, reference should be made to the following detailed description, taken in conjunction with the accompanying drawings, in which like elements are given the same or analogous reference numbers and wherein:

FIG. 1 is a view showing an example of a configuration of a solid material container;

FIG. 2 is a view showing an example of a configuration of a solid material container;

FIG. 3 is a view showing an example of a configuration of a lid unit of he solid material container;

FIG. 4 is a view showing an example of a configuration of a lid unit of he solid material container;

FIG. 5 is a view showing an example of a configuration of a solid material container;

FIG. 6 is a view showing an example of a configuration of a solid material container;

FIG. 7 is a view showing an example of a configuration of a solid material container;

FIG. 8 is a view showing an example of a configuration of a solid material container;

FIG. 9 is a view showing an example of a configuration of a solid material container;

FIG. 10 is a view of an example of a configuration of a first tray and a second tray; and

FIG. 11 is a view showing an example of a configuration of a solid material container.

### DESCRIPTION OF PREFERRED EMBODIMENTS

Several embodiments of the present invention are described below. The embodiments described below describe examples of the present invention. The present invention is not limited in any way to the following embodiments, and includes variations implemented without departing from the scope of the present invention. Note that all the configurations described below are not necessarily essential configurations of the present invention.

### Embodiment 1

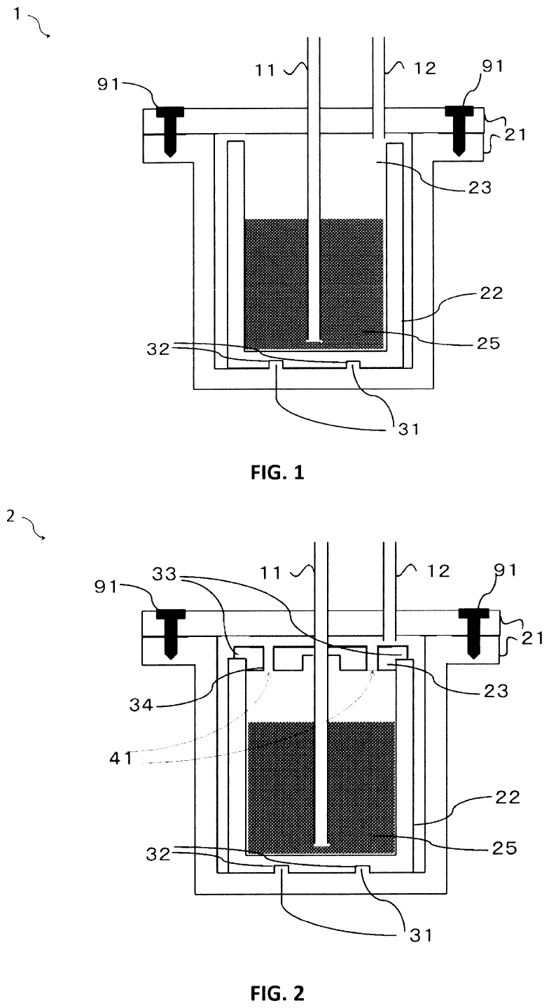

A solid material container 1 according to Embodiment 1 is described below, with reference to FIG. 1. The solid material container 1 is a solid material container for gasifying and supplying a solid material 25 contained therein.

The solid material container 1 has a carrier gas introduction pipe 11 which introduces a carrier gas into the solid material container 1, a solid material discharge pipe 12 which discharges vapor of the solid material 25 out of the solid material container 1, an outer unit 21, and an inner unit 22 which is filled with the solid material 25.

Projections 31 are formed on the inside of the outer unit 21 and a bottom section of the inner unit 22 has inner unit fitting sections 32 which removably fit with the projections 31 to the outer unit 21.

The inner unit 22 is contained inside the outer unit 21.

In FIG. 1, the projections 31 are formed on the bottom section of the inside of the outer unit 21, but they may also be formed on side surfaces of the inside of the outer unit 21. The projections 31 may be round or rectangular pillar-shaped protrusions formed on the inside of the outer unit 21, and they may be protrusions formed as a ring on the bottom section of the inside of the outer unit 21, The projections 31 may also be recesses formed on the inside of the outer unit 21.

The inner unit fitting sections 32 may be formed so as to removably fit onto the projections 31, and if the projections 31 are protrusions, then the inner unit fitting sections 32 may be recesses. If the projections 31 are recesses, then the inner unit fitting sections 32 may be protrusions.

With the solid material container 2, the outer unit 21 and the inner unit 22 are secured by fitting onto the projections 31.

Therefore, scattering of the solid material 25 filling the inner unit 22 between the outer unit 21 and the inner unit 22 can be minimized, because the inner unit 22 does not shift or tilt inside the outer unit 21.

Furthermore, scratching of the outer unit 21 and the inner unit 22 due to the inner unit 22 shifting inside the outer unit 21 can be prevented.

There is a clearance of about 1 mm between the inner unit 22 and the outer unit 21, but the clearance may have any width. It is possible to provide a clearance which takes into account thermal expansion of the materials used in the inner unit 22 and the outer unit 21 at the temperature at which the solid material container 1 is used. If there is no thermal expansion to take into account, then it is also possible for there to be no clearance.

The vapor of the solid material 25 may be discharged from the solid material container 1 just as vapor by applying vacuum depressurization after the solid material container 1, or a carrier gas may be introduced into the solid material container 1 and the vapor of the solid material 25 may be discharged accompanied by the carrier gas.

Note that in this specification, the inner unit 22 includes a section where the solid material 25 fills the inner unit 22 and a space where the inner unit 22 is not filled with the solid material 25, and the outer unit 21 includes a section where the inner unit is contained, and a space where the inner unit 22 is not contained.

The outer unit 21 need only have a capacity capable of containing the inner unit 22, and may be cylindrical or cubed. The outer unit 21 is made out of metal.

The carrier gas introduction pipe 11 and the solid material discharge pipe 12 need only be pipes which allow gas to pass therethrough, and may be made out of metal.

If the outer unit 21, the inner unit 22, the carrier gas introduction pipe 11 and the solid material discharge pipe 12 are made out of metal, they may be made out of, but not limited to, stainless steel, aluminum, aluminum alloys, copper, or copper alloys, for example. Examples of products in common circulation include, but are not limited to, Inconel™, Monel™, and HasteHoy™,

The solid material 25 may be a precursor used in depositing a semiconductor layer. The solid material 25 may be the precursor itself, or the solid material 25 carried on a carrier body such as beads, etc. The solid material 25 may be in a solid state when being filled, it may be a solid material 25 when the solid material container is being transported, and it may be in a liquid state when being filled or when being heated after being filled. There is no particular limitation on the solid material 25, which may be a material including a compound selected from the group consisting of an organic compound, an organic metal compound, a metal halide, and mixtures of these. It may be AlCl₃, HfCl₄, WCl₅, WCl₅, NbF₅, TiF₄, XeF₂, or carboxylic acid anhydride, for example.

The solid material product is obtained by filling the solid material container 1 with the solid material 25.

The carrier gas is not limited to any particular gas, and may be nitrogen, argon, helium, dry air, or hydrogen, or a combination thereof. An inert gas which does not cause a chemical reaction with the solid material 25 is selected.

The inner unit 22 has a volume capable of being contained in the outer unit 21, and is the section where the solid material 25 can be filled. The inner unit 22 has a bottom section and side surfaces, and an opening through which the solid material 25 is filled. In the inner unit 22 shown in FIG. 1 the bottom section and the side surfaces are formed as a single unit, but it is also possible to dispose the bottom section and the side surfaces of the inner unit separately but without gaps therebetween, and adhere the separate bottom section and the side surfaces together.

In the solid material container 1 shown in FIG. 1, the inner unit 22 is fitted into the outer unit 21 and the inner unit 22 is filled with the solid material 25. Thereafter, the lid of the outer unit 21, having the carrier gas introduction pipe 11 is closed. The lid of the outer unit 21 may be secured with screws 91. The solid material product is obtained by filling the solid material container 1 with the solid material 25.

The carrier gas introduced through the carrier gas introduction pipe 11 is fed to the bottom section of the inner unit 22 through an outlet of the carrier gas introduction pipe 11. The carrier gas thus fed comes in contact with the solid material 25 filling the inner unit 22 and is discharged through the solid material discharge pipe 12, accompanied by the vapor of the solid material 25.

With this configuration, the solid material container 1 having the inner unit 22 inside can stop the solid material filling the inner unit 22 from scattering out of the inner unit 22 so readily.

### Embodiment 2

A solid material container 2 according to Embodiment 2 is described below, with reference to FIG. 2. Elements having the same reference numerals as in the solid material container 1 in Embodiment 1 perform the same functions, and therefore descriptions thereof are omitted.

The solid material container 2 according to Embodiment 2 further has a lid unit 23 disposed on top of the inner unit 22, and the lid unit 23 has a plurality of upper ventilation sections 41 through which the vapor of the solid material 25 passes.

The lid unit 23 is disposed so as to prevent the solid material 25 filling the inner unit 22 from scattering between the outer unit 21 and the inner unit 22 by covering the opening on the top of the inner unit 22. If the inner unit 22 is cylindrical, the lid unit 23 is disk-shaped.

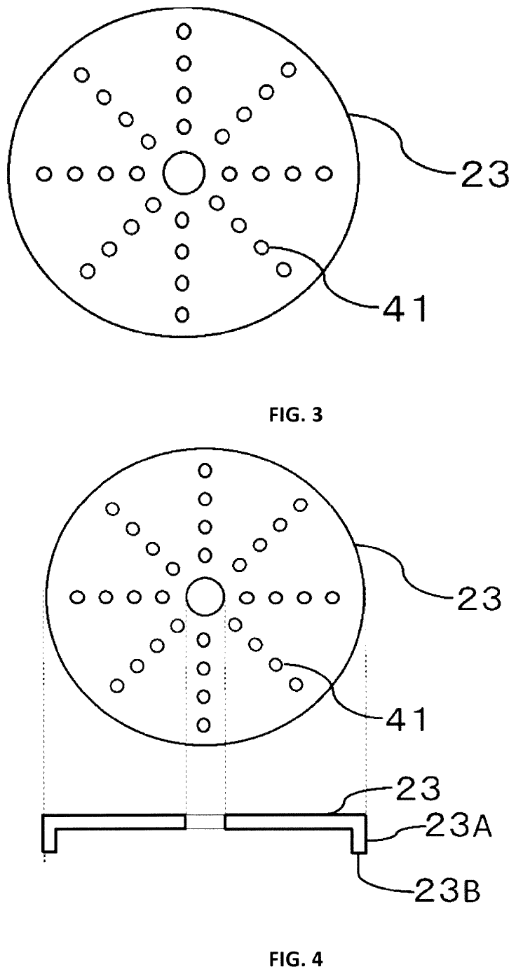

One or more upper ventilation sections 41 through which the vapor of the solid material 25 passes are disposed in the lid unit 23. The vapor of the solid material 25 may be accompanied by a carrier gas. The upper ventilation sections 41 may be any shape through which gas can pass, such as slit-shaped or in the shape of cylindrical holes. As shown in FIG. 3, there may be a showerhead arrangement in which a plurality of cylindrical holes are arranged a predetermined intervals.

The lid unit 23 may be a flat disk as shown in FIG. 3, or it may be Petri-dish-shaped, with a raised surrounding edge 23A as shown in FIG. 4. If it is Petri-dish-shaped, then it is possible for a fitting section (not shown in the drawings) to be formed on a bottom edge 23B of the surrounding edge 23A of the lid unit 23 allowing removable fitting with the top of the inner unit 22.

The lid unit 23 of the solid material container 2 has a lid unit fitting section 33 which removably fits onto the top of the inner unit 22. There is no particular limitation on the shape of the fitting sections, but if the top of the inner unit 22 is convex, then the lid unit fitting section 33 may be made concave, so as to allow fitting therebetween. If the top of the inner unit 22 is concave, then the lid unit fitting section 33 may be formed so as to be convex, thereby allowing fitting therebetween. In FIG. 2, the center of the lid unit 23 is formed circularly thicker (reference numeral 34 in FIG. 2) around the inner edges of the cylindrical inner unit 22 and the outer edges of the lid unit 23 (reference numeral 33 in the drawing FIG. 2) are formed thinner, thereby forming the lid unit fitting section 33 and allowing fitting onto the top of the inner unit 22.

The carrier gas introduced through the carrier gas introduction pipe 11 is fed to the bottom section of the inner unit 22 through an outlet of the carrier gas introduction pipe 11. The carrier gas thus fed comes in contact with the solid material 25 filling the inner unit 22, passes through the upper ventilation sections 41 disposed in the lid unit 23 accompanied by the vapor of the solid material 25, and is discharged through the solid material discharge pipe 12.

In the solid material container 2 described above, the opening of the inner unit 22 which is filled with the solid material 25 is covered by the lid unit 23, making it possible to minimize scattering of the solid material 25 out of the inner unit 22.

### Embodiment 3

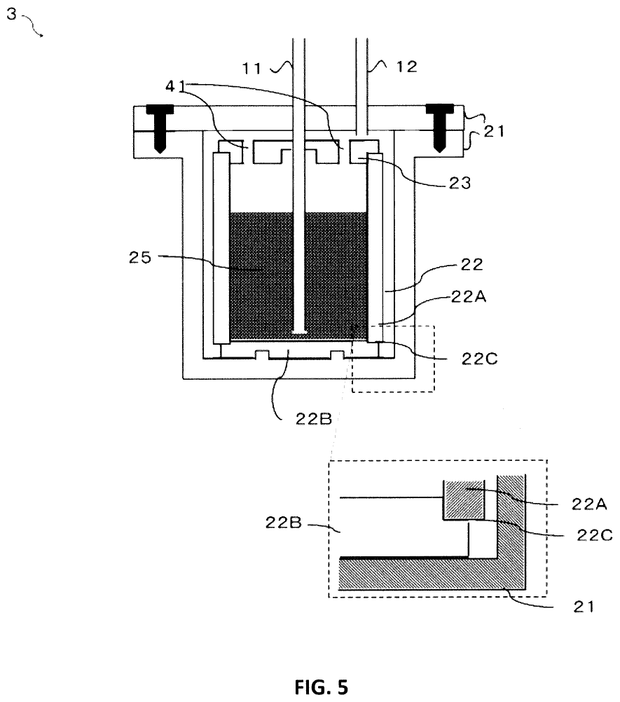

A solid material container 3 according to Embodiment 3 is described below, with reference to FIG. 5. Elements having the same reference numerals as in the solid material container 1 in Embodiment 1 and the solid material container 2 in Embodiment 2 perform the same functions, and therefore descriptions thereof are omitted.

The inner unit 22 of the solid material container 3 according to Embodiment 3 has inner unit side walls 22A and an inner unit bottom plate 22B, the inner unit side walls 22A having a bottom section fitting section 22C which removably fits onto the inner unit bottom plate 22B.

The inner unit side walls 22A and the inner unit bottom plate 22B are made separately, so machining is easier than when forming the inner unit 22 which is a single unit. In FIG. 5, steps are formed in the inner unit bottom plate 22B, and the inner unit side walls 22A are disposed so as to fit into the steps. The inner unit side walls 22A and the inner unit bottom plate 22B are fitted in the bottom section fitting section 22C, and therefore the solid material 25 filling the inner unit 22 does not leak out of the inner unit 22. The inner unit side walls 22A and the inner unit bottom plate 22B can be adhered together. Note that in FIG. 5, an enlarged view of the vicinity of the bottom section fitting section 22C is given. In order to make the enlarged view easier to see, the inner unit side walls 22A, the inner unit bottom plate 22B, and the outer unit 21 are grayed out or cross-hatched.

The shape of the fitting section 22C is not limited to a step shape. For example, recesses can be provided to the inner unit bottom plate 22B, and protrusions, which are the bottom section fitting section 22C, can be formed in the inner unit bottom plate 22B so as to fit into the recesses.

### Embodiment 4

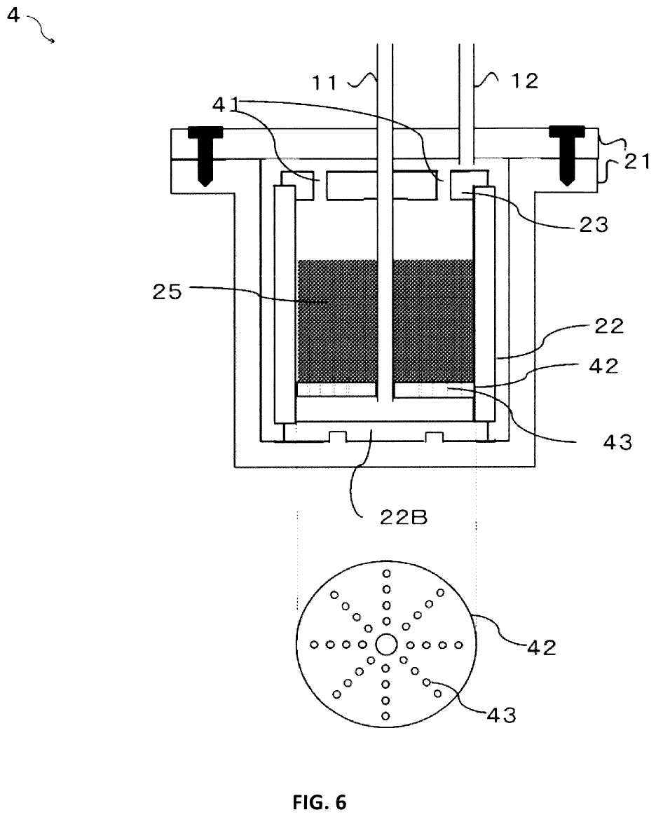

A solid material container 4 according to Embodiment 4 is described below, with reference to FIG. 6. Elements having the same reference numerals as in the solid material containers 1-3 in Embodiments 1-3 perform the same functions, and therefore descriptions thereof are omitted.

An inner unit bottom plate 42 is disposed in the bottom section of the inner unit 22 of the solid material container 4 according to Embodiment 4, and the inner unit bottom plate 42 has one or more bottom ventilation sections 43 through which carrier gas flows.

The inner unit bottom plate 42 is disposed a predetermined distance away from the inner unit bottom plate 22B. The predetermined distance may be any distance allowing the carrier gas to flow therethrough, and may be between 1 mm and 30 mm, inclusive, for example. The inner unit bottom plate 42 may be secured to the inner unit side walls 22A.

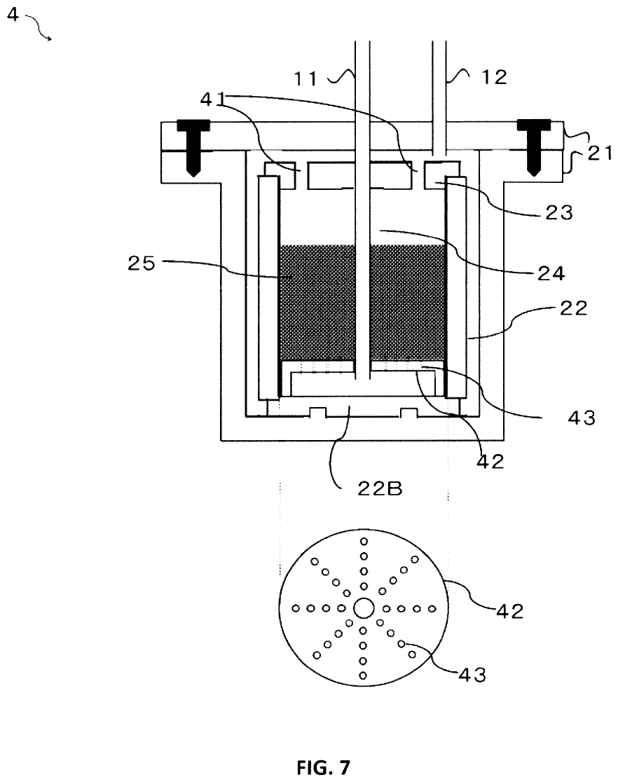

The inner unit bottom plate 42 may be a flat disk or it may be shaped like a Petri-dish with a raised surrounding edge. If the inner unit bottom plate 42 has a surrounding edge, the inner unit bottom plate 42 may be disposed such that this surrounding edge is disposed on the inner unit bottom plate 22B (see FIG. 7).

The carrier gas introduced through the carrier gas introduction pipe 11 is fed from the outlet side end of the carrier gas introduction pipe 11 towards the inner unit bottom plate 22B, passes through the bottom ventilation sections 43 in the inner unit bottom plate 42, and comes in contact with the solid material 25 filling the inner unit 22.

The bottom ventilation sections 43 need only have a shape allowing the carrier gas to pass therethrough, e.g., a slit shape, and one or more cylindrical holes may be disposed. The carrier gas fed out of the carrier gas introduction pipe 11 is dispersed by passing through the bottom ventilation sections 43, and can therefore come in contact with the solid material 25 more uniformly.

### Embodiment 5

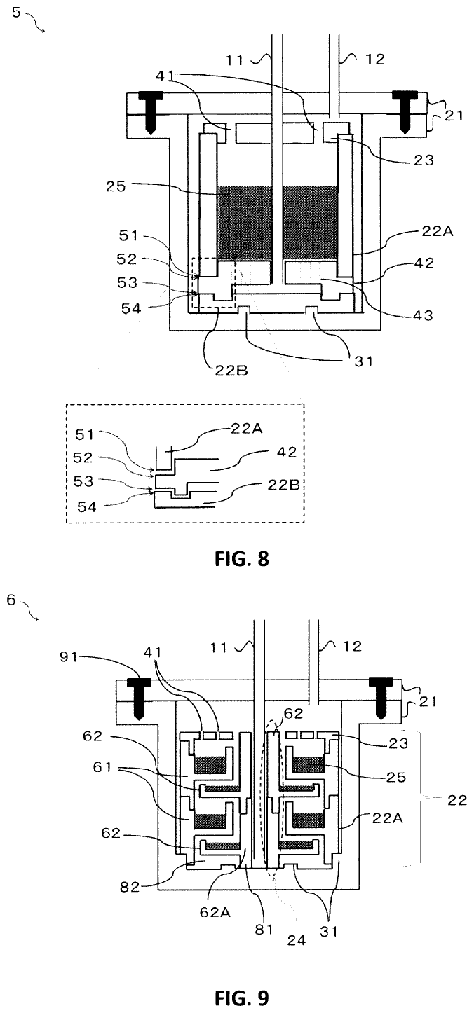

A solid material container 5 according to Embodiment 5 is described below, with reference to FIG. 8. Elements having the same reference numerals as in the solid material containers 1-4 in Embodiments 1-4 perform the same functions, and therefore descriptions thereof are omitted.

The inner unit side walls 22A of the solid material container 5 according to Embodiment 5 has a plate section top surface fitting section 51 which removably fits with a bottom plate top surface fitting section 52 disposed on the top surface of the inner unit bottom plate 42. The inner unit bottom plate 22B has a plate section bottom surface fitting section 54 which removably fits with a bottom plate bottom surface fitting section 53 which is disposed on the bottom surface of the inner unit bottom plate 42. An enlarged view of the vicinity of the bottom plate top surface fitting section 52 is shown at bottom left. Note that to make the enlarged view easier to see, spaces are included between the inner unit side walls 22A and the inner unit bottom plate 42 and between the inner unit bottom plate 42 and the inner unit bottom plate 22B, but in reality these sections are in contact with each other.

The bottom plate top surface fitting section 52 need only be formed so as to be removably fitted onto the plate section top surface fitting section 51. If the bottom plate top surface fitting section 52 is a protrusion, the plate section top surface fitting section 51 may be a recess. If the bottom plate top surface fitting section 52 is a recess, then the plate section top surface fitting section 51 may be a protrusion.

Similarly, the bottom plate bottom surface fitting section 54 need only be formed so as to be removably fitted onto the plate section bottom surface fitting section 53. If the bottom plate bottom surface fitting section 54 is a protrusion, the plate section bottom surface fitting section 53 may be a recess. If the bottom plate bottom surface fitting section 54 is a recess, then the plate section bottom surface fitting section 53 may be a protrusion.

In the solid material container 5 according to Embodiment 5, the carrier gas is introduced through the carrier gas introduction pipe 11, and is fed from the outlet end of the carrier gas introduction pipe 11 to the inner unit bottom plate 22B. The carrier gas passes through the bottom ventilation sections 43 of the inner unit bottom plate 42 and comes in contact with the solid material 25 filling the inner unit 22,

The carrier gas fed out of the carrier gas introduction pipe 11 is dispersed by passing through the bottom ventilation sections 43, and can therefore come in contact with the solid material 25 more uniformly.

The inner unit bottom plate 22B is fitted into and affixed to the outer unit 21 by the projections 31.

The inner unit bottom plate 42 is affixed to the inner unit bottom plate 22B by the plate section bottom surface fitting section 53 and the bottom plate bottom surface fitting section 54 being fitted into each other.

The inner unit side walls 22A is affixed to the inner unit bottom plate 42 by the plate section top surface fitting section 51 being fitted to the bottom plate top surface fitting section 52.

Therefore, in the outer unit 21, the inner unit side walls 22A, the pipe cover unit 24 (not shown), the inner unit bottom plate 42, and the inner unit bottom plate 22B, which make up the inner unit 22, are fixed so as not to shift, preventing the solid material 25 from scattering out of the inner unit 22 into the outer unit 21.

### Embodiment 6

A solid material container 6 according to Embodiment 6 is described below, with reference mainly to FIG. 9. Elements having the same reference numerals as in the solid material containers 1-5 in Embodiments 1-5 perform the same functions, and therefore descriptions thereof are omitted.

The solid material container 6 according to Embodiment 6 has first trays 61 and second trays 62 which are disposed at fixed intervals vertically and are filled with the solid material 25.

The first trays 61 have an outer supporting section 61A on side edges (indicated by the cross-hatching in FIG. 11). The outer dimension of the first trays 61 is smaller than the inner dimension of the outer unit 21.

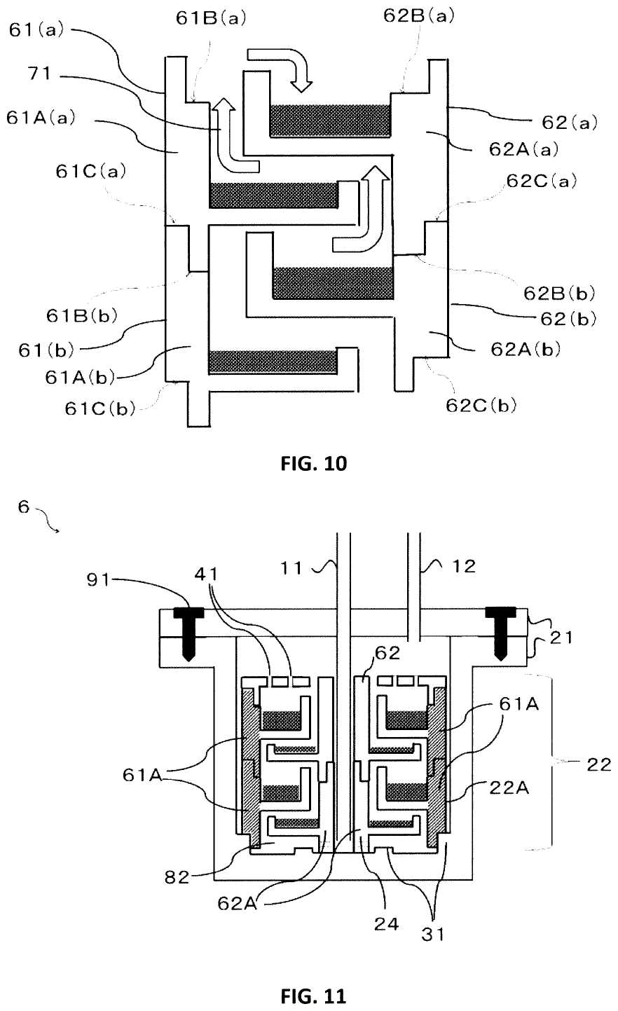

As shown in FIG. 11, the second trays 62 have an inner supporting section 62A (indicated by the shading in FIG. 11). The outer dimension of the second trays 62 is configured so as to be smaller than the outer dimension of the first trays 61 so as to form an outer flow path 71 (see FIG. 10).

The first trays 61 are disposed so as to form a vertical overlapping stack with the second trays 62.

FIG. 10 is an enlarged view of part of the left-hand side of he inner structure of FIG. 9.

A fluid flow path is provided between the first trays 61 and the second trays 62, along the outer flow path 71.

The first tray 61(a)) disposed on top has an outer supporting section top fitting section 61B(a) provided on top of an outer supporting section 61A(a), and an outer supporting section bottom fitting section 61C(a) which is provided to the bottom of the outer supporting section 61A(a).

The first tray 61(b) disposed on the bottom has an outer supporting section top fitting section 61B(b) provided on top of an outer supporting section 61A(b), and an outer supporting section bottom fitting section 61C(b) which is provided to the bottom of an outer supporting section 61A(b).

The second tray 62(a) disposed on top has an inner supporting section top fitting section 62B(a) provided on top of an inner supporting section 62A(a), and an inner supporting section bottom fitting section 62C(a) which is provided to the bottom of the inner supporting section 62A(a).

The second tray 62(b) disposed on the bottom has an inner supporting section top fitting section 62B(b) provided on top of an inner supporting section 62A(b), and an inner supporting section bottom fitting section 62C(b) which is provided to the bottom of the inner supporting section 62A(b).

The outer supporting section top fitting section 61B(b) of the bottom first tray 61(b) is removably fitted so as to be stacked on the outer supporting section bottom fitting section 61C(a) of at least one of the vertically neighboring first trays 61(a)) so as to be stacked. The shape of the outer support section top fitting section 61B(a) or 61B(b) may be a circular or squared protrusion or recess. The outer supporting section bottom fitting section 61C(a) may be any shape which allows fitting with the shape of the outer supporting section top fitting section 61B(b), and may be a round or squared recess or protrusion.

The inner supporting section top fitting section 62B(b) of the bottom second tray 62(b) is removably fitted so as to be stacked on the inner supporting section bottom fitting section 62C(a) of at least one of the vertically neighboring second trays 62(a) so as to be stacked. The shape of the inner support section top fitting section 62B(a) or 62B(b) may be a circular or squared protrusion or recess. The inner supporting section bottom fitting section 62C(a) may be any shape which allows fitting with the shape of the inner supporting section top fitting section 62B(b), and may be a round or squared recess or protrusion.

The first trays 61 and the second trays 62 are alternatingly stacked from the bottom upward in this order: first tray 61(b), second tray 62(b), first tray 61(a)), and second tray 62(a).

The second tray 62 at the very bottom is fixed in a predetermined location inside the outer unit 21 by being removably fitted to the projections 31 provided to the bottom surface of the outer unit 21 (see FIG. 9).

The bottommost first tray 61(b) is fixed in a predetermined location inside the outer unit 21 by being removably fitted to another of the projections 31 provided to the surrounding edge of the bottom section of the outer unit 21 (see FIG. 9).

Gas flow in the solid material container 6 is described next, with reference mainly to FIG. 9,

The carrier gas is introduced into the solid material container 6 through the carrier gas introduction pipe 11, The carrier gas introduction pipe 11 is made out of metal but is covered by the pipe cover unit 24 formed by stacking the inner supporting sections 62A (see FIG. 11) of the second trays 62, and therefore the solid material 25 does not come in contact with the carrier gas introduction pipe 11 which is made out of metal.

The carrier gas supplied through the outlet end of the carrier gas introduction pipe 11 passes through a flow path 81 provided to the bottom of the inner supporting section 62A of the bottommost second tray 62, and enters a bottom space 82 of the bottommost second tray 62. Thereafter, the carrier gas passes through the outer flow path (71 in FIG. 10) and enters the second trays 62,

The carrier gas, which has passed over the solid material 25 filling the second trays 62 flows into the first trays 61 along the inner supporting section 62A of the second trays 62. The carrier gas which has flowed into the first trays 61 flows over the solid material 25 filling the first trays 61 and flows into the first trays 61 via the outer flow path 71. The carrier gas thus alternatingly passes through the first trays 61 and the second trays 62, through the upper ventilation sections 41, and is discharged through the solid material discharge pipe 12,

In FIG. 9, the lid unit 23 is removably fitted onto the outer support section bottom fitting section 61B (see FIG. 10) of the first trays 61, The center of the lid unit 23 has the upper ventilation sections 41 so as to form a fluid flow path with the inner supporting sections 62A (see FIG. 10) of the second trays 62.

The solid material container 6 has the lid unit 23, but the lid unit 23 may also not be used.

Even in cases where the solid material container 6 does not have the lid unit 23, the same function as the lid 23 can be played by not filling the uppermost tray (the tray located on top, be it one of the trays 61 or one of the trays 62) with the solid material.

### EXAMPLES

### Example 1

Using the solid material container 4 according to Embodiment 4, a solid material product was made, using aluminum chloride as the solid material.

The material of the outer unit 21 and the inner unit side walls 22A, the inner unit bottom plate 22B, and the inner unit bottom plate 42 which make up the inner unit 22 is stainless steel (SUS 316L).

The outer dimensions of the outer unit 21 in the solid material container 4 are a diameter of 200 mm and a height of 185 mm. The outer dimensions of the inner unit 22 are 186 mm and a height of 132 mm.

Aluminum chloride having a purity of 99.999% was used for the aluminum chloride. 1.1 kg of the aluminum chloride was filled.

Inside a glove box having a nitrogen atmosphere, the inner unit 22 contained in the outer unit 21 was filled with the aluminum chloride, and the lid unit 23 was closed. The outer unit 21 was sealed with the screws 91, and a solid material product in which the solid material container 4 was filled with aluminum chloride was obtained. The solid material product was removed from the glove box, and the solid material container 4 was placed in a vehicle and transported 200 km to see how the aluminum chloride scattered. After transportation, the solid material container 4 was opened inside a glove box with a nitrogen atmosphere and the interior was observed.

No attachment of the aluminum chloride was observed when the inner surfaces of the outer unit were inspective visually. No aluminum chloride was observed between the outer unit 21 and the inner unit 22, either. A small amount of aluminum chloride was observed to be attached to the inside of the lid unit 23. There was no change in the weight of the aluminum chloride filling the inner unit following transportation.

### Comparison Example 1

A solid material container was created using a container having the same structure as in Example 1 but lacking the projections 31 and the inner unit fitting sections 32, and using aluminum chloride as the solid material. The outer dimensions of the outer unit 21 in the solid material container 4 are a diameter of 200 mm and a height of 185 mm. The outer dimensions of the inner unit 22 are 186 mm and a height of 132 mm.

Aluminum chloride having a purity of 99.999% was used for the aluminum chloride. 1.1 kg of the aluminum chloride was filled.

Inside a glove box having a nitrogen atmosphere, the inner unit 22 contained in the outer unit 21 was filled with the aluminum chloride, and the lid unit 23 was closed. The outer unit 21 was sealed with the screws 91, and a solid material product in which the solid material container 4 was filled with aluminum chloride was obtained. The solid material product was removed from the glove box, and the solid material container 4 was placed in a vehicle and transported 200 km to see how the aluminum chloride scattered.

When the inner surfaces of the outer unit were observed, a large amount of the aluminum chloride inside the inner unit 22 had entered into the space between the inner unit 22 and the outer unit 21.

Of the 1.1 kg of aluminum chloride filling the inner unit 22, only 1.02 kg was left in the inner unit 22 after being transported 200 km.

### Example 2

Using a solid material container which was the same as in Example 1, was filled with the same amount (1.1 kg) of the aluminum chloride, which was the same solid material, and was transported under the same transportation conditions, a supply test of the aluminum chloride vapor was carried out.

Specifically, the solid material container 4, which had been transported 200 km, was heated to 130° C., a carrier gas was introduced, and the aluminum chloride vapor was discharged from the solid material container 4. Nitrogen gas was used as the carrier gas, with a flow rate of 500 SCCM.

The aluminum chloride vapor was discharged until the remainder of the solid material 25 in the solid material container 4 was 10% of the original filling amount (i.e., until only 110 g of the aluminum chloride remained in the solid material container 4). Thereafter, the solid material container 4 was cooled to 25° C., and the interior was visually inspected inside a glove box with a nitrogen atmosphere.

When the inner surfaces of the outer unit were visually observed, no aluminum chloride was found between the inner unit and the outer unit.

The aluminum chloride remaining in the inner unit was white, and no corrosion was visually observed. Moreover, the aluminum chloride remaining in the inner unit had a uniform thickness.

As a result, it is likely that in Example 2 the aluminum chloride vapor was accompanied by the carrier gas uniformly, without the solid material tilting inside the container or scattering out of the inner unit during transportation or usage.

### Comparison Example 2

As in Comparison Example 1, using a solid material container was used which was the same container, but lacking the projections 31 and the inner unit fitting sections 32, was filled with the same amount (1.1 kg) of aluminum chloride, which is the same solid material, and transported under the same transportation conditions, an aluminum chloride vapor supply test was carried out. Specifically, the solid material container 4, which had been transported 200 km, was heated to 130° C., a carrier gas was introduced, and the aluminum chloride vapor was discharged from the solid material container 4. Nitrogen gas was used as the carrier gas, with a flow rate of 500 SCCM.

The aluminum chloride vapor was discharged until the remainder of the solid material 25 in the solid material container 4 was 10% of the original filling amount (i.e., until only 110 g of the aluminum chloride remained in the solid material container 4). Thereafter, the solid material container 4 was cooled to 25° C., and the interior was visually inspected inside a glove box with a nitrogen atmosphere.

When the inner surfaces of the outer unit were inspected visually, approximately 20 g of a gray solid substance was found between the outer unit and the bottom section of the inner unit. The solid material container 4 is heated from the outside by an electric heater, so the outer unit, which comes directly in contact with the heater, gets hotter than the inner unit. Accordingly, in Comparison Example 2, it is thought that the aluminum chloride spilled out of the inner unit into the bottom section of the outer unit, and this spilled aluminum chloride was excessively heated, resulting in corrosion or denaturing.

Furthermore, the aluminum chloride remaining in the inner unit had collected on one side of the inner unit. It is conceivable that the aluminum chloride collected in the inner unit during transportation, and that the aluminum chloride was vaporized while being heated in this uneven manner. It is conjectured that because the carrier gas was introduced with the aluminum chloride collected on one side, contact between the carrier gas and the aluminum chloride was inadequate under conditions of reduced remaining amount.

### Example 3

Using the solid material container 6 according to Embodiment 6, a solid material product was made, using aluminum chloride as the solid material.

The material of the outer unit 21 and the first trays 61 and the second trays 62 making up the inner unit 22 was stainless steel (SUS 316L).

The outer dimensions of the outer unit 21 in the solid material container 6 are a diameter of 200 mm and a height of 310 mm. The outer dimensions of the inner unit 22 are 186 mm and a height of 274 mm.

All the first trays and the second trays were filled with a total of 6.01 kg of the aluminum chloride.

When the outer unit 21, which had been transported 200 km as in Example 1, was visually inspected, no attachment of the aluminum chloride was found. No aluminum chloride was found between the outer unit 21 and the first trays 61 or the second trays 62. A very small amount of aluminum chloride was found on the ceiling of the outer unit 21.

There was no change in the weight of the aluminum chloride filling the inner unit fallowing transportation.

### Comparison Example 3

A solid material product was made using a container having the same structure as in Example 3, but lacking the projections 31, the inner unit fitting sections 32, the fitting sections for fitting neighboring first trays together, and the fitting sections for fitting neighboring second trays together, and using aluminum chloride as the solid material.

A solid material product in which the first trays and the second trays of the unit 22 contained in the outer unit 21 were filled with 6.02 kg of the aluminum chloride inside a glove box having a nitrogen atmosphere, was obtained. The solid material product was removed from the glove box, and the solid material container 6 was placed in a vehicle and transported 200 km to see how the aluminum chloride scattered.

When the inner surfaces of the outer unit were observed, a large amount of the aluminum chloride inside the inner unit 22 had entered into the space between the outer unit 21 and the first trays and the second trays, A large amount of aluminum chloride was attached to the inside of the ceiling of the outer unit 21.

Of the 6.00 kg of aluminum chloride filling the inner unit 22, only 5.68 kg was left in the inner unit 22 after being transported 200 km.

On the basis of the results in Example 1 and Comparison Example 1, the structure of the solid material 6 container in which the inner unit and the outer unit are fitted together by the projections and the inner unit fitting sections was found to be able to minimize scattering of the solid material 25 out of the inner unit.

Similarly, on the basis of the results of Example 2 and Comparison Example 2, the structure in which the inner unit and the outer unit are fitted together with the projections and the inner unit fitting sections, the first trays are fitted together, and the second trays are fitted together was found to be able to minimize scattering of the solid material 25 from the first trays and the second trays.

### Example 4

Using a solid material container which was the same as in Example 3, was filled with the same amount (6.01 kg) of the aluminum chloride, which was the same solid material, and was transported under the same transportation conditions, a supply test of the aluminum chloride vapor as in Example 2 was carried out.

Specifically, the solid material container, which had been transported 200 km, was heated to 130° C., a carrier gas was introduced, and the aluminum chloride vapor was discharged from the solid material container 4. Nitrogen gas was used as the carrier gas, with a flow rate of 500 SCCM. The total flow rate of the carrier gas and the solid material vapor discharged from the solid material container was measured using a mass flow meter provided to the back end of the solid material discharge pipe.

The aluminum chloride vapor was discharged until the remainder of the solid material in the solid material container was 10% of the original filling amount (i.e., until only 600 g of the aluminum chloride remained in the solid material container). Thereafter, the solid material container was cooled to 25° C., and the interior was visually inspected inside a glove box with a nitrogen atmosphere.

The flow rate as measured by the mass flow meter was constant from when starting the solid material vapor supply until when only approximately 10% of the solid material remained.

When the inner surfaces of the outer unit were visually observed, no aluminum chloride was found between the inner unit and the outer unit.

All the first trays were fitted into neighboring first trays above and below, and there were no trays with visually observable gaps. Similarly, all the second trays were fitted into neighboring second trays above and below, and there were no trays with visually observable gaps.

Almost no aluminum chloride remained in the lower first trays and the lower second trays.

A small amount of the aluminum chloride remained in the upper first trays and the upper second trays. The aluminum chloride on the trays remained uniformly in the first trays and the second trays, and there was no uneven distribution seen inside the trays.

The aluminum chloride remaining in first trays and the second trays was white, and no corrosion was visually observed.

As a result, it is likely that in Example 4 the aluminum chloride vapor was accompanied by the carrier gas uniformly, without the solid material tilting inside the container or scattering out of the inner unit during transportation or usage.

### Comparison Example 4

As in Comparison Example 3, using a solid material container was used which was the same container, but lacking the projections 31, the inner unit fitting sections 32, the fitting sections for fitting together neighboring first trays, the fitting sections for fitting together neighboring second trays, and was filled with the same amount (1.1 kg) of aluminum chloride, which is the same solid material, and transported under the same transportation conditions, an aluminum chloride vapor supply test was carried out.

Specifically, the solid material container, which had been transported 200 km, was heated to 130° C., a carrier gas was introduced, and the aluminum chloride vapor was discharged from the solid material container 4. Nitrogen gas was used as the carrier gas, with a flow rate of 500 SCCM. The total flow rate of the carrier gas and the solid material vapor discharged from the solid material container was measured using a mass flow meter provided to the back end of the solid material discharge pipe.

The aluminum chloride vapor was discharged until the remainder of the solid material in the solid material container was 10% of the original filling amount (i.e., until only 600 g of the aluminum chloride remained in the solid material container). Thereafter, the solid material container was cooled to 25° C., and the interior was visually inspected inside a glove box with a nitrogen atmosphere.

The flow rate as measured by the mass flow meter displayed a gradual falling tendency from when starting the solid material vapor supply until when only approximately 10% of the solid material remained.

When the inner surfaces of the outer unit were inspected visually, a large amount of a solid substance was found between the outer unit and the bottom section of the inner unit.

Attachment of the aluminum chloride was found between the outer unit and the inner unit.

The solidified aluminum chloride was attached in gaps created between the edges of the first trays above and below.

The second trays were stacked vertically.

Aluminum chloride remained in the lower and upper first trays and the lower and upper second trays, and was unevenly distributed inside the trays.

On the basis of these results, it is thought that the first trays moved inside the outer unit, and neighboring upper and lower first trays shifted, causing the aluminum chloride filling at least the first trays to scatter out of the first trays. Moreover, when the first trays shifted, this created gaps between the outer unit and the first trays, and it is thought that there was inadequate contact between the carrier gas and the aluminum chloride due to the carrier gas flowing through those gaps. Part of the carrier gas passing through the lower first trays and the lower second trays flowed into the space between the first trays and the outer unit through those gaps, and the amount of carrier gas flowing into the upper first trays and the upper second trays fell. Furthermore, because of the uneven distribution of the aluminum chloride inside the trays, it is thought that there were places where the aluminum chloride remained in the trains and places where the solid material did not remain, exposing the metal surface of the trays, once the remaining amount had fallen. Therefore, contact between the solid material and the carrier gas flowing over the trays was inadequate. Accordingly, it is thought that the flow rate measured by the mass flow meter fell.

From the above results, it was found that securing the outer unit and the inner unit (or trays) by fitting them together is effective in minimizing the phenomenon of solid material scattering out of the inner unit (or trays). It was also found that it is effect to dispose the trays without gaps therebetween by fitting them together in a solid material container having an inner unit in which a plurality of trays are disposed, in order to achieve uniform discharge of solid material vapor.

### EXPLANATION OF THE REFERENCE NUMERALS

1. Solid material container

2. Solid material container

3. Solid material container

4. Solid material container

5. Solid material container

6. Solid material container

11. Carrier gas introduction pipe

12. Solid material discharge pipe

21. Outer unit

22. Inner unit

22A. Inner unit side walls

22B. Inner unit bottom section

22C. Bottom section fitting section

23. Lid unit

23A. Raised surrounding edge

23B. Bottom edge

24. Pipe cover unit

25. Solid material

31. Projections

32. Inner unit fitting sections

33. Lid unit fitting section

41. Upper ventilation sections

42. Inner unit bottom plate

43. Bottom ventilation sections

51. Plate section top surface fitting section

52. Bottom plate top surface fitting section

53. Plate section bottom surface fitting section

54. Bottom plate bottom surface fitting section

61. First trays

61(a). First tray

61(b). First tray

61A. Outer supporting section

61A(a). Outer supporting section

61A(b). Outer supporting section

61B. Outer supporting section top surface fitting section

61B(a). Outer supporting section top fitting section

61B(b). Outer supporting section top fitting section

61C. Outer supporting section bottom surface fitting section

61C(a). Outer supporting section bottom fitting section

61C(b). Outer supporting section bottom fitting section

62. Second trays

62(a). Second trays

62(b). Second trays

62A. Inner supporting section

62A(a). Inner supporting section

62A(b). Inner supporting section

62B. Inner supporting section top surface fitting section

62B(a). Inner supporting section top fitting section

62B(b). Inner supporting section top fitting section

62C. Inner supporting section bottom surface fitting section

62C(a). Inner supporting section bottom fitting section

62C(b). Inner supporting section bottom fitting section

71. Outer flow path

81. Flow path

82. Bottom space

91. Screws

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations as fall within the spirit and broad scope of the appended claims. The present invention may suitably comprise, consist or consist essentially of the elements disclosed and may be practiced in the absence of an element not disclosed, Furthermore, if there is language referring to order, such as first and second, it should be understood in an exemplary sense and not in a limiting sense. For example, it can be recognized by those skilled in the art that certain steps can be combined into a single step.

The singular forms “a”, “an” and “the” include plural referents, unless the context clearly dictates otherwise,

“Comprising” in a claim is an open transitional term which means the subsequently identified claim elements are a nonexclusive listing (i.e., anything else may be additionally included and remain within the scope of “comprising”). “Comprising” as used herein may be replaced by the more limited transitional terms “consisting essentially of” and “consisting of” unless otherwise indicated herein,

“Providing” in a claim is defined to mean furnishing, supplying, making available, or preparing something. The step may be performed by any actor in the absence of express language in the claim to the contrary,

Optional or optionally means that the subsequently described event or circumstances may or may not occur. The description includes instances where the event or circumstance occurs and instances where it does not occur.

Ranges may be expressed herein as from about one particular value, and/or to about another particular value. When such a range is expressed, it is to be understood that another embodiment is from the one particular value and/or to the other particular value, along with all combinations within said range.

All references identified herein are each hereby incorporated by reference into this application in their entireties, as well as for the specific information for which each is cited.

1. A solid material container for gasifying and supplying a solid material contained therein, comprising a solid material discharge pipe which discharges a vapor of the solid material out of the solid material container, a metal outer unit, and a metal inner unit, wherein
the inner unit is contained inside the outer unit and protrusions are formed on the inside of the outer unit, and
a bottom section of the inner unit has an inner section fitting section which removably fits onto the protrusions with the outer unit.

2. The solid material container as claimed in claim 1, further comprising a lid unit disposed on top of the inner unit, wherein the lid unit has at least one upper ventilation section through which the vapor of the solid material flows.

3. The solid material container as claimed in claim 2, wherein the lid unit has a lid section fitting section which removably fits onto the top of the inner unit.

4. The solid material container claim 1, wherein the inner unit has inner unit side walls and an inner unit bottom section, and the inner unit side walls have a bottom section fitting section which removably fits onto the inner unit bottom section.

5. The solid material container of claim 4, wherein an inner section bottom plate is disposed in the inner unit bottom section, and the inner unit bottom plate has one or more bottom ventilation sections through which the carrier gas passes.

6. The solid material container as claimed in claim 5, wherein the inner unit side walls have plate section top surface fitting sections which removably fit onto a bottom plate top surface section disposed on the top surface of the inner unit bottom plate, and the inner unit bottom section has a plate section bottom surface fitting section which removably fits with a bottom plate bottom surface fitting section disposed on a bottom surface of the inner unit bottom plate.

7. The solid material container of claim 6, wherein the inner unit has a plurality of trays which are disposed at predetermined intervals vertically and which are filled with the solid material.

8. The solid material container as claimed in claim 7, wherein the plurality of trays comprise at least one first tray which has an outer supporting section on side edges thereof and is smaller than the inner dimension of the outer unit, and at least one second tray, which has an inner supporting section in a central section thereof and is smaller than the outer dimension of the first tray for forming an outer flow path, wherein the first tray is disposed so as to form an overlapping vertical stack with a neighboring second tray, and a fluid flow path is provided between the first tray and the second tray passing through the outer flow path.

9. The solid material container according to claim 8, wherein the first tray has an outer supporting section top fitting section provided to the top of the outer supporting section, and an outer supporting section bottom fitting section provided to the bottom of the outer supporting section, the second tray has an inner supporting section top fitting section provided to the top of the inner supporting section, and an inner supporting section bottom fitting section provided to the bottom of the inner supporting section, the outer supporting section top fitting section of at least one of the first trays is removably fitted so as to be stacked on the outer supporting section bottom fitting section of at least one of the vertically neighboring first trays, and the inner supporting section top fitting section of at least one of the first trays is removably fitted so as to be stacked on the inner supporting section bottom fitting section of at least one of the vertically neighboring first trays.

10. A solid material product in which a solid material fills the solid material container as claimed in claim 1.
